(19) United States
(12) Patent Application Publication
(10) Pub. No.: US 2026/0013315 A1
(43) Pub. Date: Jan. 8, 2026

(54) POLYMER COMPOSITE ELECTRODE, METHOD FOR MANUFACTURING THE SAME, AND ORGANIC ELECTRONIC DEVICE COMPRISING THE SAME

(71) Applicant: GWANGJU INSTITUTE OF SCIENCE AND TECHNOLOGY, Gwangju (KR)

(72) Inventors: Kwang Hee LEE, Gwangju (KR); Dong Hyun KANG, Gwangju (KR); Ju Hyeon KIM, Gwangju (KR); Hong kyu KANG, Gwangju (KR)

(21) Appl. No.: 19/253,710

(22) Filed: Jun. 27, 2025

(30) Foreign Application Priority Data
Jul. 4, 2024 (KR) 10-2024-0088342

(51) Int. Cl. H10K 30/82; H10K 30/50; H10K 50/81; H10K 71/60; H10K 85/10; H10K 85/20; H10K 85/60; H10K 101/40

(52) U.S. Cl. CPC H10K 30/82; H10K 30/50; H10K 50/81; H10K 71/60; H10K 85/1135; H10K 85/215; H10K 85/626; H10K 85/655; H10K 85/656; H10K 85/6576; H10K 2101/40

(57) ABSTRACT

The present inventive concept relates to a polymer composite electrode with a tunable work function and high conductivity, a method for manufacturing the same, and an organic electronic device including the polymer composite electrode. According to the present inventive concept, the polymer composite electrode, prepared by adding a perfluorinated polymer compound of Formula 1 to a conductive polymer PEDOT: PSS, followed by sulfuric acid treatment, has a high transmittance of 85% or more in the visible light region and an average electrical conductivity of 2,000 S/cm or higher. Moreover, the work function of the polymer composite electrode can be matched to the highest occupied molecular orbital (HOMO) energy level of the photoactive layer by adjusting the concentration of the perfluorinated polymer compound of Formula 1. Accordingly, even when the photoactive layer is directly formed on the polymer composite electrode without a hole transport layer, efficient hole transport can still be achieved, and thus, the polymer composite electrode can be usefully employed as an anode in optoelectronic devices such as organic solar cells, serving as a viable alternative to conventional ITO.

### CROSS-REFERENCE TO RELATED PATENT APPLICATION

This application claims the benefit of Korean Patent Application No. 10-2024-0088342, filed on Jul. 4, 2024, in the Korean Intellectual Property Office, the disclosure of which is incorporated herein in its entirety by reference.

### BACKGROUND

### 1. Technical Field

The present inventive concept relates to a polymer electrode, and more particularly, to a polymer composite electrode with a tunable work function and high conductivity, a method for manufacturing the same, and an organic electronic device employing the same.

### 2. Description of the Related Art

Electronic devices incorporating flexible plastic transparent electrodes integrate multiple scientific technologies, offering lightweight and flexible properties that make them highly suitable for applications in the emerging ubiquitous era. A critical aspect of advancing such electronic devices is the development of flexible plastic transparent electrodes.

Transparent electrodes are being widely applied in various devices such as flat panel displays including LCDs, PDPs, and OLEDs, touch screens, and thin-film solar cells.

The most representative transparent electrode currently in use is indium tin oxide (ITO), which exhibits excellent optical and electrical properties. However, due to its brittle nature, ITO has limitations in application to next-generation flexible devices, and since it requires a high-temperature deposition process, it also presents challenges in the fabrication of high-performance transparent electrodes through printing processes.

Moreover, due to the limited reserves of indium, which is the main raw material of ITO, and the resulting increase in its price, there is an urgent need for the development of new types of transparent electrodes.

Meanwhile, interest in conductive polymers as transparent electrodes to replace ITO has been steadily increasing. These conductive polymers, composed of organic materials, retain the advantages of conventional plastics—such as ease of processing, lightweight properties, flexibility, simple coating procedures, and low production costs—while their electrical conductivity continues to advance, approaching levels comparable to those of metals. Furthermore, they have a high transmittance in the visible light region, making them viable candidates as alternatives to ITO. In addition, conductive polymers offer the advantage of being processable through low-temperature solution-based processes.

Poly(3,4-ethylenedioxythiophene): poly(styrenesulfonate) (PEDOT: PSS), a representative conductive polymer, is one of the most widely used conductive plastic materials, as it exhibits high conductivity, excellent transmittance in the visible light region, superior environmental compatibility due to its water dispersibility that enables solution processing, and outstanding stability. However, its conductivity is as low as approximately 1 S/cm for use as a transparent electrode, which is significantly lower than that of ITO (>5,000 S/cm), and also falls short of the typical conductivity (approximately 2,000 S/cm) required for electrodes used in electronic devices.

Additionally, conventional transparent electrode materials have fixed work function values, which require multilayered and complex structures for high-performance electronic devices, thereby increasing the complexity of the fabrication process of electronic devices.

Accordingly, in order to simplify the fabrication process of the electronic devices and to fabricate high-performance electronic devices, there is a need for the development of a flexible transparent electrode that has a tunable work function and high conductivity.

### SUMMARY

The present inventive concept has been made in an effort to solve the above-described problems associated with prior art, and an object of the present inventive concept is to provide a method for manufacturing a flexible transparent electrode with a tunable work function and high conductivity.

Another object of the present inventive concept is to provide an organic electronic device comprising an electrode manufactured by the above-described method.

The object of the present inventive concept is not limited to those mentioned above, and other objects not mentioned will be clearly understood by those skilled in the art to which the inventive concept pertains from the description below.

In order to achieve the aforementioned objectives, one aspect of the present inventive concept provides a method for manufacturing a polymer composite electrode. The method may comprise the following steps: (S10) Preparing a polymer composite solution by mixing a perfluorinated polymer compound, represented by Formula 1 below, with a conductive polymer solution; (S20) Forming a polymer composite thin film by applying the polymer composite solution onto a substrate; (S30) Treating the polymer composite thin film with sulfuric acid; and

(S40) Washing and drying the sulfuric acid-treated polymer composite thin film to complete the manufacturing of the polymer composite electrode:

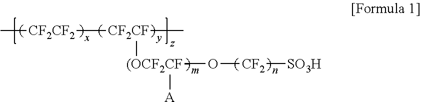

where x is a real number from 1 to 20,
y is a real number from 1 and 2,
z is a real number from 10 to 1,000,
A is F or CF₃,
m is a real number of 0 or 1, and
n is a real number from 1 to 20.

The perfluorinated polymer compound of Formula 1 may be a polymer represented by Formula 2 or Formula 3 below:

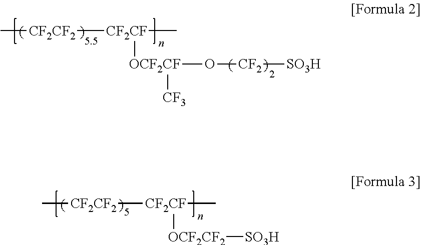

where n is a real number from 10 to 1,000.

If the conductive polymer is a PEDOT: PSS polymer and the perfluorinated polymer compound is a polymer of Formula 2, the concentration of the perfluorinated polymer compound may be in the range of 1 vol % to 10 vol % based on the PEDOT: PSS polymer solution.

If the conductive polymer is a PEDOT: PSS polymer and the perfluorinated polymer compound is a polymer of Formula 3, the concentration of the perfluorinated polymer compound may be in the range of 0.5 vol % to 2 vol % based on the PEDOT: PSS polymer solution.

The step of treating the polymer composite thin film with sulfuric acid may comprise immersing the polymer composite thin film in sulfuric acid.

The step of washing the polymer composite thin film treated with sulfuric acid may be carried out using water.

Another aspect of the present inventive concept provides a polymer composite electrode. The polymer composite electrode may be prepared by mixing a PEDOT: PSS conductive polymer and a perfluorinated polymer compound of Formula 1 below, wherein the polymer composite electrode may have a work function, which is reduced to −5.4 eV or lower depending on the concentration of the perfluorinated polymer compound of Formula 1 mixed with the conductive polymer, an average electrical conductivity of 2,000 S/cm or higher, and a transmittance of 85% or more in the visible light region:

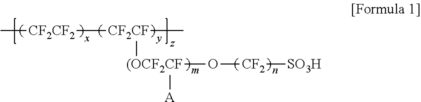

where x is a real number from 1 to 20,
y is a real number from 1 and 2,
z is a real number from 10 to 1,000,
A is F or CF₃,
m is a real number of 0 or 1, and
n is a real number from 1 to 20.

In the polymer composite electrode, the perfluorinated polymer compound of Formula 1 may be a polymer represented by Formula 2 or Formula 3 below:

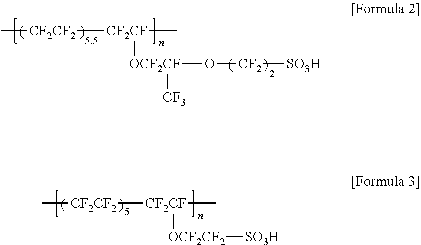

where n is a real number from 10 to 1,000.

Still another aspect of the present inventive concept provides an organic electronic device comprising the polymer composite electrode. The organic electronic device may comprise: a substrate; an anode formed on the substrate; a photoactive layer formed on the anode; and a cathode located on the photoactive layer. The anode may be a polymer composite electrode prepared by mixing a PEDOT: PSS conductive polymer and a perfluorinated polymer compound of Formula 1 below, wherein the polymer composite electrode may have a work function, which is reduced to −5.4 eV or lower depending on the concentration of the perfluorinated polymer compound of Formula 1 mixed with the conductive polymer, an average electrical conductivity of 2,000 S/cm or higher, and a transmittance of 85% or more in the visible light region:

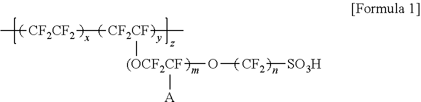

where x is a real number from 1 to 20,
y is a real number from 1 and 2,
z is a real number from 10 to 1,000,
A is F or CF₃,
m is a real number of 0 or 1, and
n is a real number from 1 to 20.

In the organic electronic device, the perfluorinated polymer compound of Formula 1 may be a polymer represented by Formula 2 or Formula 3 below:

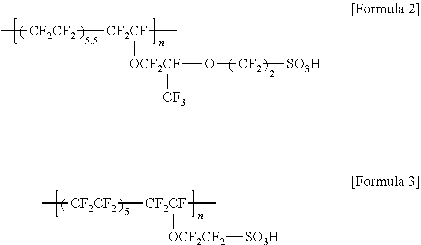

where n is a real number from 10 to 1,000.

In the organic electronic device, the work function of the polymer composite electrode can be matched to the highest occupied molecular orbital (HOMO) energy level of the photoactive layer by adjusting the concentration of the perfluorinated polymer compound of Formula 1 mixed with the conductive polymer.

In the organic electronic device, the polymer composite electrode may have an average electrical conductivity of 2,000 S/cm or higher and a transmittance of 85% or more in the visible light region.

In the organic electronic device, the photoactive layer may be a light-emitting layer or a photoelectric conversion layer.

The organic electronic device may further comprise an electron transport layer between the photoactive layer and the cathode.

According to the present inventive concept, the polymer composite electrode, prepared by adding a perfluorinated polymer compound of Formula 1 to a conductive polymer PEDOT: PSS, followed by sulfuric acid treatment, has a high transmittance of 85% or more in the visible light region and an average electrical conductivity of 2,000 S/cm or higher. Moreover, the work function of the polymer composite electrode can be matched to the highest occupied molecular orbital (HOMO) energy level of the photoactive layer by adjusting the concentration of the perfluorinated polymer compound of Formula 1. Accordingly, even when the photoactive layer is directly formed on the polymer composite electrode without a hole transport layer, efficient hole transport can still be achieved, and thus, the polymer composite electrode can be usefully employed as an anode in optoelectronic devices such as organic solar cells, serving as a viable alternative to conventional ITO.

### BRIEF DESCRIPTION OF THE DRAWINGS

The above and other features and advantages of the present inventive concept will become more apparent by describing in detail exemplary embodiments thereof with reference to the attached drawings in which:

FIG. 1 is a flowchart illustrating a method for manufacturing a polymer composite electrode with a tunable work function and high conductivity according to an embodiment of the present inventive concept;

FIG. 2 is a schematic diagram of an organic electronic device comprising a polymer composite electrode manufactured according to an embodiment of the present inventive concept;

FIG. 3 is a graph showing the change in the work function of polymer composite electrodes, prepared by adding a Nafion polymer compound of Formula 2 to PEDOT: PSS, followed by sulfuric acid treatment, according to an embodiment of the present inventive concept, depending on the concentration of the Nation polymer compound and the presence or absence of sulfuric acid treatment;

FIG. 4 is a graph showing the change in the work function of polymer composite electrodes, prepared by adding an Aquivion polymer compound of Formula 3 to PEDOT: PSS, followed by sulfuric acid treatment, according to an embodiment of the present inventive concept, depending on the concentration of the Aquivion polymer compound and the presence or absence of sulfuric acid treatment;

FIG. 5 is a graph showing the change in the electrical conductivity of polymer composite electrodes, prepared by adding the Nation polymer compound of Formula 2 to PEDOT: PSS, followed by sulfuric acid treatment, according to an embodiment of the present inventive concept, depending on the concentration of the Nation polymer compound;

FIG. 6 is a graph showing the change in the electrical conductivity of polymer composite electrodes, prepared by adding the Aquivion polymer compound of Formula 3 to PEDOT: PSS, followed by sulfuric acid treatment, according to an embodiment of the present inventive concept, depending on the concentration of the Aquivion polymer compound;

FIG. 7 is a graph showing the change in the transmittance of polymer composite electrodes, prepared by adding the Nation polymer compound of Formula 2 to PEDOT: PSS, followed by sulfuric acid treatment, according to an embodiment of the present inventive concept, depending on the concentration of the Nation polymer compound;

FIG. 8 is a graph showing the change in the transmittance of polymer composite electrodes, prepared by adding the Aquivion polymer compound of Formula 3 to PEDOT: PSS, followed by sulfuric acid treatment, according to an embodiment of the present inventive concept, depending on the concentration of the Aquivion polymer compound;

FIG. 9 is a graph showing the changes in both the electrical conductivity and transmittance of polymer composite electrodes, prepared by adding the Nation polymer compound of Formula 2 to PEDOT: PSS, followed by sulfuric acid treatment, according to an embodiment of the present inventive concept, depending on the concentration of the Nafion polymer compound;

FIG. 10 is a graph showing the changes in both the electrical conductivity and transmittance of polymer composite electrodes, prepared by adding the Aquivion polymer compound of Formula 3 to PEDOT: PSS, followed by sulfuric acid treatment, according to an embodiment of the present inventive concept, depending on the concentration of the Aquivion polymer compound;

FIG. 11 is a schematic diagram of an organic electronic device fabricated according to an embodiment of the present inventive concept;

FIG. 12 is an energy band diagram of an organic electronic device fabricated according to an embodiment of the present inventive concept;

FIG. 13 is an energy band diagram of organic electronic devices fabricated according to an embodiment of the present inventive concept, comprising various types of photoactive layer materials; and

FIG. 14 is a graph showing the power conversion efficiency (PCE) of organic electronic devices comprising various types of photoactive layer materials, wherein the organic electronic devices according to embodiments of the present inventive concept use a polymer composite electrode without a hole transport layer, compared to the organic electronic devices using an ITO electrode without a hole transport layer according to Comparative Examples.

### DETAILED DESCRIPTION

Hereinafter, preferred embodiments of the present inventive concept will be described in more detail with reference to the accompanying drawings in order to provide a more specific description of the inventive concept. However, the present inventive concept is not limited to the embodiments described herein and may be embodied in other forms.

Throughout this specification, when a part is referred to as “including” a certain component, it is to be understood that, unless explicitly stated otherwise, the part may further include other components and does not exclude the presence of other components.

As used herein, the terms ‘about’ and ‘substantially’ denote a degree of approximation relative to the stated value, encompassing any material tolerances applicable within the relevant context. These terms serve to facilitate the understanding of the present disclosure and to prevent unfair exploitation through rigid interpretation of precise or absolute values.

Furthermore, when referring to an element—such as a layer, region, or substrate—being ‘on’ another element, it should be understood that the element may be directly positioned on the other element or may include one or more intervening structures therebetween.

Additionally, the use of terms such as ‘first’ and ‘second’ to describe various elements, components, regions, layers, or sections is not intended to impose limitations on such elements. These terms are solely employed for distinguishing purposes and should not be construed as implying any specific ordering or hierarchy.

### Polymer Composite Electrodes

One aspect of the present inventive concept provides a method for manufacturing a polymer composite electrode.

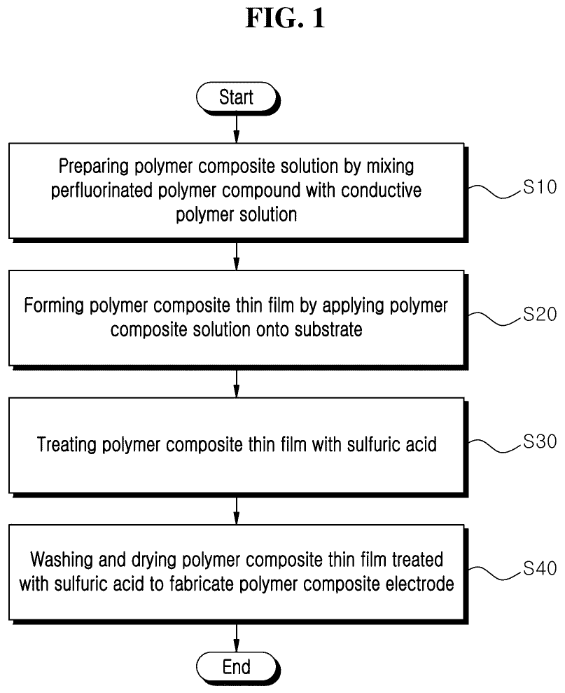

FIG. 1 is a flowchart showing a method for manufacturing a polymer composite electrode according to an embodiment of the present inventive concept.

Referring to FIG. 1, the method for manufacturing a polymer composite electrode according to an embodiment of the present inventive concept may comprise:
a step (S10) of preparing a polymer composite solution by mixing a perfluorinated polymer compound represented by Formula 1 below with a conductive polymer solution;
a step (S20) of forming a polymer composite thin film by applying the polymer composite solution onto a substrate;
a step (S30) of treating the polymer composite thin film with sulfuric acid; and
a step (S40) of washing and drying the polymer composite thin film treated with sulfuric acid to manufacture a polymer composite electrode:

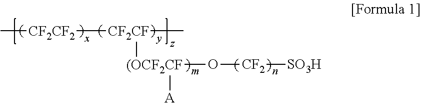

where x is a real number from 1 to 20,
y is a real number from 1 and 2,
z is a real number from 10 to 1,000,
A is F or CF₃,
m is a real number of 0 or 1, and
n is a real number from 1 to 20.

The method for manufacturing a polymer composite electrode according to the present inventive concept will be described in detail step by step as follows.

First, step S10 involves preparing a polymer composite solution.

The polymer composite solution may be prepared by mixing a perfluorinated polymer compound of Formula 1 with a conductive polymer solution.

The conductive polymer may be a poly(3,4-ethylenedioxythiophene): poly(styrenesulfonate) (PEDOT: PSS) polymer.

The PEDOT: PSS polymer is a composite in which poly(styrenesulfonate) (PSS), an anionic dopant, is introduced into poly(3,4-ethylenedioxythiophene) (PEDOT), a polythiophene-based conductive polymer. It can exist as a stable dispersion in water and exhibits excellent thermal stability.

Accordingly, the conductive polymer solution may be a solution in which the PEDOT: PSS polymer is dispersed in water.

The PEDOT: PSS polymer may have a solid content of PEDOT and PSS adjusted in a range of 10 wt % to 15 wt % to maintain optimal dispersibility in water.

Furthermore, the PEDOT: PSS polymer is well miscible with water, alcohol, or solvents having a high dielectric constant, and thus can be easily diluted with such solvents for coating. Even after forming a coating film, it exhibits superior transparency compared to other conductive polymers such as polyaniline-based or polypyrrole-based polymers.

In the case of the PEDOT: PSS polymer, the anionic PSS is present around the electrically conductive PEDOT polymer due to intermolecular interactions. The PSS serves to improve the dispersibility of PEDOT in solvents by preventing its stacking. However, the low electrical conductivity of PSS can lead to the formation of non-conductive molecular chains around PEDOT, which may result in an overall reduction in the electrical conductivity of the electrode.

Furthermore, the PEDOT: PSS polymer has a fixed work function value of −4.78 eV. As a result, when used alone, it presents a significant energy level mismatch with the HOMO of the main semiconductor material, which typically ranges from approximately −5.1 eV to −6.1 eV. To facilitate efficient electrical interaction between the PEDOT: PSS polymer and the main semiconductor material, it is necessary to introduce additional charge and hole transport layers with varying energy levels. However, this requirement adversely impacts cost competitiveness.

The fixed work function of the PEDOT: PSS polymer can be tuned by forming a polymer composite through mixing (blending) with the perfluorinated polymer compound of Formula 1.

The perfluorinated polymer compound of Formula 1 may have a fluorine substituent, and a sulfonic group at the terminal end. The fluorine substituent exhibits minimal reactivity with the elements in the PEDOT: PSS polymer, and thus, when mixed with the PEDOT: PSS polymer, it induces a change in the material's work function without altering the physical properties of the PEDOT: PSS polymer. Specifically, the PEDOT: PSS material exhibits an increase in its work function value (−4.7 to −4.8 eV) due to the hygroscopic nature of the PSS material. When the perfluorinated polymer compound of Formula 1 is mixed with this PEDOT: PSS material, the perfluorinated polymer compound of Formula 1 replaces the position of PSS, resulting in the formation of a polymer composite. As a result, the composite exhibits enhanced hydrophobic properties, and its work function value approaches the work function value (approximately −6.0 eV) of the original PEDOT material. Furthermore, through the sulfuric acid treatment described later, the PSS material in the polymer composite is removed, resulting in a further reduction in the work function value of the polymer composite material. This is believed to be due to the combination of the enhanced hydrophobic properties and the effect of the perfluorinated polymer compound of Formula 1, which induces the formation of an electric dipole moment within the polymer composite material, thereby influencing the change in the work function. Therefore, increasing the concentration of the perfluorinated polymer compound of Formula 1 may result in the formation of a polymer composite with an even lower work function value.

The perfluorinated polymer compound of Formula 1 may include, but is not limited to, a Nafion polymer of Formula 2 or an Aquivion polymer of Formula 3 below:

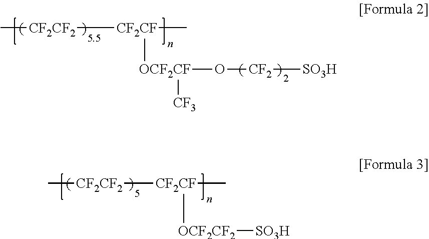

where n is a real number from 10 to 1,000.

At this time, the work function value of the resulting polymer composite can be tuned depending on the concentration of the perfluorinated polymer compound. For example, to fabricate an electrode with a work function of approximately −5.5 eV that matches the highest occupied molecular orbital (HOMO) energy level of the photoactive layer, the concentration of the perfluorinated polymer compound of Formula 2 can be adjusted to a range of 1 vol % to 10 vol % based on the PEDOT: PSS polymer solution, while the concentration of the perfluorinated polymer compound of Formula 3 can be adjusted to a range of 0.5 vol % to 2 vol % based on the PEDOT: PSS polymer solution.

Next, step S20 involves forming a polymer composite thin film.

The polymer composite thin film can be formed by applying the polymer composite solution prepared in step S10 onto a substrate.

The substrate may be selected from a group comprising glass, quartz, Al₂O₃, and SiC; however, selection is not limited to these materials. Preferably, materials such as glass, which are resistant to corrosion under the sulfuric acid post-treatment conditions described later, may be used.

The polymer composite thin film may be formed by performing a solution process in which the polymer composite solution is applied onto the substrate.

Examples of the solution process include dip coating, spin coating, roll coating, and spray coating. These solution processes are advantageous in terms of printability, cost-effectiveness, and the feasibility of low-temperature processing.

The thickness of the polymer composite thin film may be in the range of 20 nm to 200 nm, which can be advantageous in terms of reducing sheet resistance.

Next, step S30 involves treating the polymer composite thin film with sulfuric acid.

Specifically, the polymer composite thin film formed in step S20 is treated with sulfuric acid. Treating the polymer composite thin film with sulfuric acid involves exposing the thin film to sulfuric acid, which may be done by spraying, coating, or immersion. Among these, immersion may be preferred for its simplicity and potential to maximize reaction efficiency.

The sulfuric acid (H₂SO₄) undergoes autoprotolysis, in which two sulfuric acid (H₂SO₄) molecules generate two ions as follows:

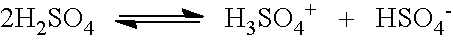

Therefore, when the polymer composite thin film is post-treated with sulfuric acid, the anionic HSO₄⁻ surrounds the PEDOT regions within the polymer composite thin film, while the cationic H₃SO₄⁺ surrounds the PSS regions within the polymer composite thin film. This weakens the intermolecular forces between PEDOT and PSS, thereby inducing a “charge-separated transition state”.

In other words, when the polymer composite thin film containing PEDOT: PSS is treated with highly concentrated H₂SO₄, the two ions stabilize the separated state of positively charged PEDOT and negatively charged PSS. Consequently, the strong π-π stacking interactions of PEDOT, along with the rigidity of its backbone, facilitate the formation of a dense PEDOT network. The initially amorphous PEDOT: PSS particles undergo a transformation into crystalline nanofibril structures, leading to significant changes in both crystallinity and morphology. Ultimately, the PEDOT: PSS polymer within the composite thin film undergoes structural rearrangement, forming crystalline PEDOT: PSS nanofibrils, while the excess non-conductive PSS component is dissociated and removed.

At this point, since PEDOT is a conductive material and PSS is non-conductive, it is believed that the electrical conductivity of the polymer composite thin film comprising PEDOT: PSS can be improved by leaving only the minimum amount of PSS necessary to maintain the structure of PEDOT: PSS.

The time during which the polymer composite thin film is immersed may vary depending on the concentration of sulfuric acid; however, it is believed that a duration of at least one minute is sufficient for the reaction. No structural changes in PEDOT were observed even after one week of immersion, and there was no impact on electrical conductivity, so no upper limit is set.

The sulfuric acid is preferably used in a relatively ultra-high concentration, specifically in the range of 17 M to 19 M.

Next, step S40 involves washing and drying the polymer composite thin film treated with sulfuric acid.

In this step, the polymer composite thin film, having undergone sulfuric acid treatment, is washed to remove the PSS dissociated from the film. While water can serve as a washing agent, it is not limited thereto, with deionized water being particularly preferred. Meanwhile, the minimal amount of PSS necessary to maintain the PEDOT: PSS structure may undergo reorganization into PEDOT, where it functions as a counter ion. Furthermore, the crystallinity of the PEDOT: PSS in the polymer composite before sulfuric acid treatment is likely to increase after the sulfuric acid treatment and washing, as the proportion of PSS is significantly reduced. This increase in crystallinity leads to an increase in charge mobility, which may further lower the work function of the polymer composite in the negative (−) direction and improve electrical conductivity.

From an electrical conductivity perspective, the crystallinity is preferably above 40%, more preferably above 46%, even more preferably above 48%, and most preferably above 50%. However, as higher crystallinity generally enhances conductivity, no specific upper limit is set.

After washing the polymer composite thin film treated with sulfuric acid, it can be dried at a temperature of 60° C. to 160° C. The drying method may include hot air drying, vacuum drying, or infrared (IR) drying. Through this drying process, a polymer composite electrode fixed in shape on the substrate can be formed.

The polymer composite electrode prepared by the above-described method has a high transmittance of 85% or more in the visible light region and an average electrical conductivity of 2,000 S/cm or higher by adding a perfluorinated polymer compound of Formula 1 to a conductive polymer, such as a PEDOT: PSS polymer, followed by sulfuric acid treatment. Moreover, by adjusting the concentration of the perfluorinated polymer compound of Formula 1, which is mixed into the conductive polymer solution during manufacturing, the work function of the polymer composite electrode can be lowered to below −5.4 eV, allowing it to match the highest occupied molecular orbital (HOMO) energy level of the photoactive layer. Accordingly, even when the photoactive layer is directly formed on the polymer composite electrode without a hole transport layer, efficient hole transport can still be achieved, and thus, the polymer composite electrode can be usefully employed as an anode in optoelectronic devices such as organic solar cells, serving as a viable alternative to conventional ITO.

Another aspect of the present inventive concept provides a polymer composite electrode. The polymer composite electrode may be prepared by mixing a PEDOT: PSS conductive polymer and a perfluorinated polymer compound of Formula 1, wherein the polymer composite electrode may have a work function, which is reduced to −5.4 eV or lower depending on the concentration of the perfluorinated polymer compound of Formula 1 mixed with the conductive polymer, an average electrical conductivity of 2,000 S/cm or higher, and a transmittance of 85% or more in the visible light region.

Detailed descriptions of the conductive polymer and perfluorinated polymer compound have been provided above, and thus, a further description will be omitted to avoid redundancy.

### Organic Electronic Devices

Still another aspect of the present inventive concept provides an organic electronic device comprising the polymer composite electrode.

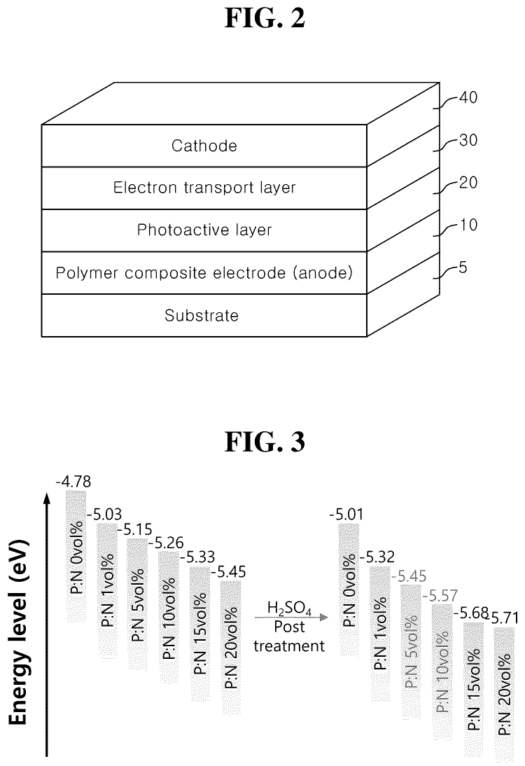

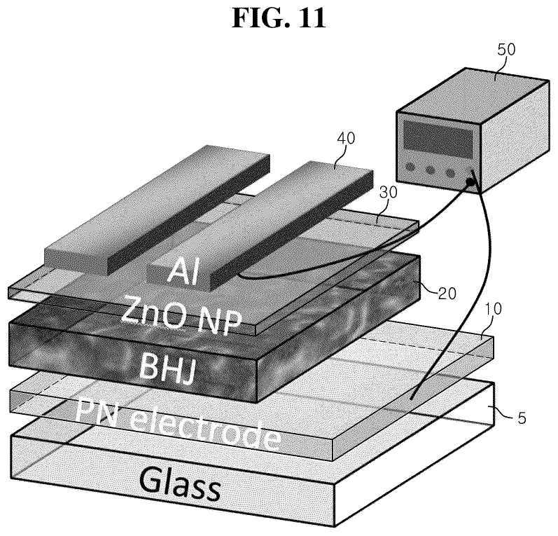

FIGS. 2 and 11 are schematic diagrams illustrating an organic electronic device according to an embodiment of the present inventive concept.

Referring to FIGS. 2 and 11, the organic electronic device may comprise an anode 10, a photoactive layer 20, an electron transport layer 30, and a cathode 40, which are sequentially formed on a substrate 5.

The organic electronic device according to the present inventive concept uses, as the anode, a polymer composite electrode in which a conductive polymer, such as a PEDOT: PSS conductive polymer, and a perfluorinated polymer compound of formula 1 are mixed, followed by sulfuric acid treatment. Upon mixing the PEDOT: PSS conductive polymer and the perfluorinated polymer compound of formula 1, the work function of the polymer composite electrode can be matched to the highest occupied molecular orbital (HOMO) energy level of the photoactive layer by adjusting the concentration of the perfluorinated polymer compound of Formula 1, thereby eliminating the need for a separate hole transport layer.

The substrate 5 serves as a structural support for the organic electronic device and may be a light-transmitting inorganic material selected from glass, quartz, Al₂O₃, and SiC. However, its selection is not limited to these materials. Since the present inventive concept involves the use of a high concentration of strong acid, it is preferable to use a material that is resistant to corrosion.

The anode 10 may be a polymer composite electrode prepared by adding the perfluorinated polymer compound of Formula 1 to the conductive polymer, followed by sulfuric acid treatment, according to the present inventive concept. This serves as a component that can replace the conventional indium tin oxide (ITO) film.

The photoactive layer 20 may be a light-emitting layer or a photoelectric conversion layer. Here, the light-emitting layer refers to a layer that generates light by the combination of electrons and holes supplied externally, while the photoelectric conversion layer refers to a layer in which the generation of electron-hole pairs (excitons) and their separation into respective charges occurs due to the light supplied externally. When the photoactive layer 20 is configured as a light-emitting layer or a photoelectric conversion layer, the organic electronic device can be fabricated as an organic light-emitting device or an organic solar cell, respectively.

The materials of the light-emitting layer and the photoelectric conversion layer are not particularly limited, and various polymeric or low-molecular-weight organic materials can be used.

For example, the material of the light-emitting layer may be selected from polypyrrole-based, polyacetylene-based, poly(3,4-polyaniline-based, ethylenedioxythiophene) (PEDOT)-based, polyphenylenevinylene (PPV)-based, polyfluorene-based, polyparaphenylene (PPP)-based, polyalkylthiophene-based, polypyridine (PPy)-based, or polyvinylcarbazole-based materials, or copolymers thereof, or may be selected from appropriate host/dopant-based materials.

For example, the photoelectric conversion layer may be a bulk heterojunction layer of an electron donor material and an electron acceptor material. In this case, the electron donor material may be selected from polythiophene-based, polyfluorene-based, polyaniline-based, polycarbazole-based, polyvinylcarbazole-based, polyphenylene-based, polyphenylvinylene-based, polysilane-based, polyisothianaphthene-based, polythiazole-based, polybenzothiazole-based, and polythiopheneoxide-based materials, or copolymers thereof. As an example, the electron donor material may be poly(3-hexylthiophene) (P3HT), which is a type of polythiophene-based material, or may comprise at least one selected from the group consisting of copolymers of the above-described polymers, such as PTB7-Th (poly[4,8-bis(5-(2-ethylhexyl)thiophen-2-yl)benzo[1,2-b; 4,5-b′]dithiophene-2,6-diyl-alt-(4-(2-ethylhexyl)-3-fluorothieno[3,4-b]thiophene-)-2-carboxylate-2-6-diyl]), PBDB-T (poly [(2,6-(4,8-bis(5-(2-ethylhexyl)thiophen-2-yl)-benzo[1,2-b: 4,5-b′]dithiophene))-alt-(5,5-(1′, 3′-di-2-thienyl-5′, 7′-bis(2-ethylhexyl)benzo[1′, 2′-c: 4′, 5′-c′]dithiophene-4,8-dione)]), PM6 (9′-(2,12-di-tert-butyl-5,9-dioxa-13b-boranaphtho[3,2,1-de]anthracen-7-yl)-9,9″-diphenyl-9H, 9′H, 9″H-3,3′: 6′, 3″-tercarbazole), PCPDTBT (poly [2,6-(4,4-bis-(2-ethylhexyl)-4H-cyclopenta [2,1-b; 3,4-b′]dithiophene)-alt-4,7-(2,1,3-benzothiadiazole)]), PCDTBT (poly [N-9″-heptadecanyl-2,7-carbazole-alt-5,5-(4′, 7′-di-2-thienyl-2′, 1′, 3′-benzothiadiazole)]), and PFDTBT (poly(2,7-(9-(2′-ethylhexyl)-9-hexyl-fluorene)-alt-5,5-(4′, 7′-di-2-thienyl-2′, 1′, 3′-benzothiadiazole))).

In addition, the electron acceptor material of the photoelectric conversion layer may be, for example, a fullerene having 60 to 84 carbon atoms (C₆₀ to C₈₄) or a derivative thereof, or a non-fullerene electron acceptor compound. The fullerene derivative may be, for example, PCBM, such as PC₆₁BM ([6,6]-phenyl-C₆₁-butyric acid methyl ester). The non-fullerene electron accepting compound may comprise at least one selected from the group consisting of ITIC (3,9-bis(2-methylene-(3-(1,1-dicyanomethylene)-indanone))-5,5, 11, 11-tetrakis(4-hexylphenyl)-dithieno[2,3-d: 2′, 3′-d′]-s-indaceno [1,2-b: 5,6-b′]dithiophene), ITIC-Th (3,9-bis(2-methylene-(3-(1,1-dicyanomethylene)-indanone))-5,5, 11, 11-tetrakis(5-hexylthienyl)-dithieno[2,3-d: 2′, 3′-d′]-s-indaceno [1,2-b: 5,6-b′]dithiophene), ITIC-M (3,9-bis(2-methylene-((3-(1,1-dicyanomethylene)-6/7-methyl)-indanone))-5,5, 11, 11-tetrakis(4-hexylphenyl)-dithieno[2,3-d: 2′, 3′-d′]-s-indaceno [1,2-b: 5,6-b′]dithiophene), IDIC (2,2′-((2Z,2′Z)-((4,4,9,9-tetrahexyl-4,9-dihydro-s-indaceno [1,2-b: 5,6-b′]dithiophene-2,7-diyl)bis(methanylylidene)) bis(3-oxo-2,3-dihydro-1H-indene-2,1-diylidene))dimalononitrile), ITIC-4F (3,9-bis(2-methylene-((3-(1,1-dicyanomethylene)-6,7-difluoro)-indanone))-5,5, 11, 11-tetrakis(4-hexylphenyl)-dithieno[2,3-d: 2′, 3′-d′]-s-indaceno [1,2-b: 5,6-b′]dithiophene), IEICO-4F ((2,2′-((2Z,2′Z)-(((4,4,9,9-tetrakis(4-hexylphenyl)-4,9-dihydro-s-indaceno [1,2-b: 5,6-b′]dithiophene-2,7-diyl)bis(4-((2-ethylhe xyl)oxy)thiophene-5,2-diyl))bis(methanylylidene)) bis(5,6-difluoro-3-oxo-2,3-dihydro-1H-indene-2,1-diylidene))dimalononitrile), IEICO-4CI (2,2′-((2Z,2′Z)-(((4,4,9-tris(4-hexylphenyl)-9-(4-pentylphenyl)-4,9-dihydro-s-indaceno [1,2-b: 5,6-b dithiophene-2,7-diyl)bis(4-((2-ethylhexyl)oxy)thiophene-5,2-diyl))bis(methanylylidene)) bis(5,6-dichloro-3-oxo-2,3-dihydro-1H-indene-2,1-diylidene))dimalononitrile), EH-IDTBR ((5Z)-3-Ethyl-2-sulfanylidene-5-[4-[9,9,18, 18-tetrakis(2-ethylhexyl)-15-[7-[(Z)-(3-ethyl-4-oxo-2-sulfanylidene-1,3-thiazolidin-5-ylidene)methyl]-2, 1,3-benzothiadiazol-4-yl]-5,14-dithiapentacyclo[10.6.0.03,10.04,8.013,17]octadeca-1 (12),2,4 (8),6,10, 13 (17), 15-heptaen-6-yl]-2, 1,3-benzothiadiazol-7-yl]methylidene]-1,3-thiazolidin-4-one), and Y6 (2,2′-((2Z,2′Z)-((12,13-Bis(2-ethylhexyl)-3,9-diundecyl-12,13-dihydro-[1,2,5]thiadiazolo[3,4-e]thieno-[2″, 3″: 4′, 5′]thieno[2′, 3′: 4,5]pyrrolo [3,2-g]thieno-[2′, 3′: 4,5]thieno[3,2-b]indole-2,10-diyl)bis(methanylylidene))-bis(5,6-difluoro-3-oxo-2,3-dihydro-1H-indene-2,1-diylidene))dimalononitrile).

The electron transport layer 30 can facilitate the transport of electrons supplied via an external circuit from the cathode 40 to the photoactive layer 20 (in the case of an organic light-emitting device) or facilitate the transport of electrons generated in the photoactive layer 20 to the cathode 40 (in the case of an organic solar cell). Additionally, the electron transport layer 30 may also serve as a hole-blocking layer that prevents holes generated in the photoactive layer 20 from being injected into the cathode 40. The electron transport layer 30 may be composed of a metal oxide layer, such as ZnO, TiO₂, Nb₂O₅, SnO₂, ZrO₂, or ternary metal oxides. In one embodiment, the electron transport layer may include ZnO nanoparticles. The electron transport layer 30 may be formed by a solution process or a deposition process.

The cathode 40 is an electrode having a lower work function than the anode 10 and may be a metal electrode or a conductive polymer electrode. For example, the cathode 40 may be a metal electrode selected from Li, Mg, Ca, Ba, Al, Cu, Ag, Au, W, Ni, Zn, Ti, Zr, Hf, Cd, Pd, Cs, and alloys thereof. In the case where the cathode 40 is a metal electrode, it may be formed by thermal vapor deposition, electron beam deposition, sputtering, or chemical deposition, or by applying a metal-containing electrode paste, followed by heat treatment; however, it is not limited thereto.

Next, preferred Preparation Examples and Experimental Examples are provided to facilitate understanding of the present inventive concept. However, these examples are presented for illustrative purposes only and are not intended to limit the scope of the present inventive concept.

### Preparation Example 1: Preparation of PEDOT: PSS-Based Polymer Composite Electrode

A 1 mL aliquot of PEDOT: PSS polymer solution was transferred into a glass vial. Subsequently, a perfluorinated polymer compound, specifically the Nation compound represented by Formula 2, was added to the solution at a volume ratio of 10 vol %. The mixture was stirred for 30 minutes to ensure thorough blending and interaction of the polymer components, thereby forming a polymer composite solution. This solution was then applied to a substrate via spin coating to produce a thin film. The resulting thin film was subsequently placed in a flask containing sulfuric acid and subjected to a reaction for 5 minutes, leading to the ionization of a portion of the PSS regions within the polymer composite. The film was then rinsed with deionized water to effectively remove the ionized PSS regions. Thereafter, to remove the solvent from the washed polymer composite thin film, a heat treatment process was carried out at 100° C. for 10 minutes to prepare the PEDOT: PSS-based polymer composite electrode.

Preparation Examples 2 to 5: Preparation of PEDOT: PSS-Based Polymer Composite Electrodes

PEDOT: PSS-based polymer composite electrodes were prepared in the same manner as in Preparation Example 1, except that the perfluorinated polymer compound of Formula 2 was added in amounts of 1 vol %, 5 vol %, 15 vol %, and 20 vol %, respectively.

### Preparation Examples 6 to 12: Preparation of PEDOT: PSS-Based Polymer Composite Electrodes

PEDOT: PSS-based polymer composite electrodes were prepared in the same manner as in Preparation Example 1, except that the compound of Formula 3 was added in amounts of 0.5 vol %, 1 vol %, 1.5 vol %, 2 vol %, 3 vol %, 4 vol %, and 5 vol %, respectively, instead of the compound of Formula 2 as the perfluorinated polymer compound.

### Comparative Example 1

An electrode was prepared in the same manner as in Preparation Example 1, except that the PEDOT: PSS was treated with sulfuric acid without the addition of the perfluorinated polymer compound.

### Comparative Example 2

An electrode with ITO deposited on a glass substrate was used.

As shown in Table 1 below, PEDOT: PSS-based polymer composite electrodes were prepared using perfluorinated polymer compounds at various concentrations:

TABLE 1

| | | Concentration of |
|---|---|---|
| | Perfluorinated Polymer | Perfluorinated Polymer |
| Examples | Compound | Compound (vol %) |
| Preparation Example 1 | Nafion^{a)} | 10 |
| Preparation Example 2 | Nafion | 1 |
| Preparation Example 3 | Nafion | 5 |
| Preparation Example 4 | Nafion | 15 |
| Preparation Example 5 | Nafion | 20 |
| Preparation Example 6 | Aquivion^{b)} | 0.5 |
| Preparation Example 7 | Aquivion | 1 |
| Preparation Example 8 | Aquivion | 1.5 |
| Preparation Example 9 | Aquivion | 2 |
| Preparation Example 10 | Aquivion | 3 |
| Preparation Example 11 | Aquivion | 4 |
| Preparation Example 12 | Aquivion | 5 |
| Comparative Example 1 | — | — |
| Comparative Example 2 | — | — |

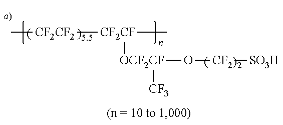

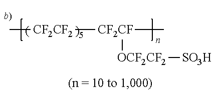

### Experimental Example 1: Change in Work Function of the Polymer Composite Electrodes Depending on the Concentration of the Perfluorinated Polymer Compound

The work function refers to the energy required to remove an electron from the surface of a solid into the vacuum. For use as an anode material in an organic solar cell, the work function needs to be lower than −5 eV.

The following experiment was conducted to investigate the change in the work function of the electrodes depending on the concentration of the perfluorinated polymer compound added to the conductive polymer in the polymer composite electrodes of the present inventive concept.

Specifically, the conductive polymer electrode of Comparative Example 1 was prepared using the conductive polymer PEDOT: PSS, followed by sulfuric acid treatment. In contrast, the polymer composite electrodes of Preparation Examples 1 to 5 were fabricated by incorporating the Nation polymer compound of Formula 2 into the conductive polymer, followed by sulfuric acid treatment. The work function of the polymer composite electrodes was measured depending on the concentration of the Nafion polymer compound and the presence or absence of sulfuric acid treatment, with the results presented in FIG. 3.

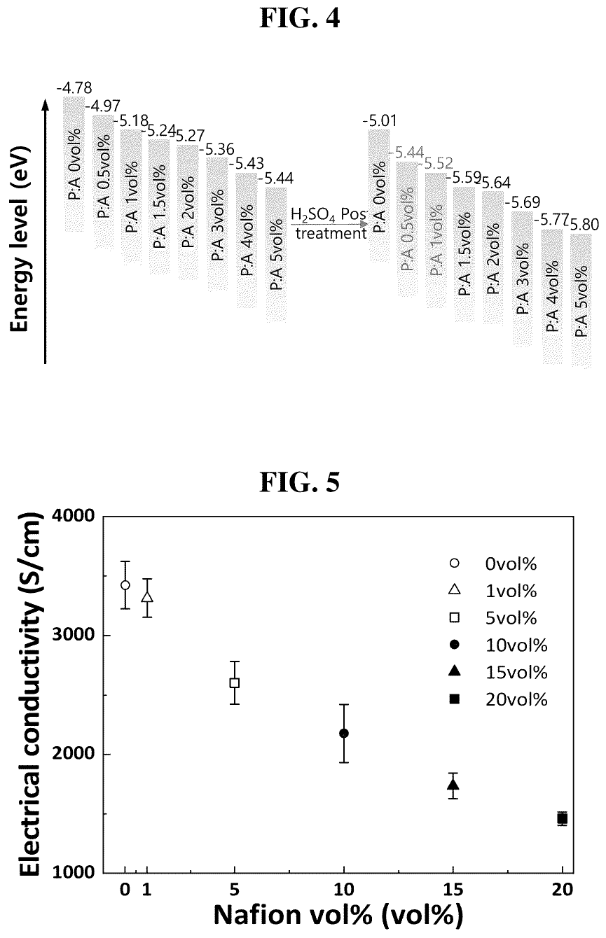

Moreover, for the polymer composite electrodes prepared by adding the Aquivion polymer compound of Formula 3 to the conductive polymer, followed by sulfuric acid treatment, according to Preparation Examples 6 to 12, the work function of the polymer composite electrodes was measured depending on the concentration of the Aquivion polymer compound and the presence or absence of sulfuric acid treatment, with the results presented in FIG. 4.

As illustrated in FIGS. 3 and 4, the thin film lacking the addition of a perfluorinated polymer compound to the conductive polymer exhibited a work function of −4.78 eV. Following sulfuric acid treatment, the work function increased to −5.01 eV. However, this still results in a substantial energy level mismatch with the highest occupied molecular orbital (HOMO) energy level of the semiconductor material in the photoactive layer, necessitating the incorporation of a hole transport layer.

By contrast, the polymer composite electrode formed by incorporating a perfluorinated polymer compound into the conductive polymer, in accordance with the present inventive concept, exhibited a work function as low as approximately −5.5 eV, depending on the concentration of the added perfluorinated polymer compound. This adjustment enables effective energy level matching with the HOMO energy level of the semiconductor material in the photoactive layer. Furthermore, following sulfuric acid treatment, the work function undergoes a further reduction, demonstrating that the polymer composite's work function continues to decrease as the concentration of the perfluorinated polymer compound of Formula 1 increases.

Therefore, the method for manufacturing a polymer composite electrode according to the present inventive concept can adjust the work function energy level by adding the perfluorinated polymer compound of Formula 2 or Formula 3 to the conductive polymer, followed by sulfuric acid treatment, thereby enabling matching with the highest occupied molecular orbital (HOMO) energy level of the semiconductor material in the photoactive layer.

### Experimental Example 2: Change in Electrical Conductivity of the Polymer Composite Electrodes Depending on the Concentration of the Perfluorinated Polymer Compound

The following experiment was conducted to investigate the change in the electrical conductivity of the electrodes depending on the concentration of the perfluorinated polymer compound added to the conductive polymer in the polymer composite electrodes of the present inventive concept.

Specifically, the conductive polymer electrode of Comparative Example 1 was prepared using the conductive polymer PEDOT: PSS, followed by sulfuric acid treatment. In contrast, the polymer composite electrodes of Preparation Examples 1 to 5 were fabricated by incorporating the Nation polymer compound of Formula 2 into the conductive polymer, followed by sulfuric acid treatment. The electrical conductivity of the polymer composite electrodes was measured depending on the concentration of the Nafion polymer compound, with the results presented in FIG. 5.

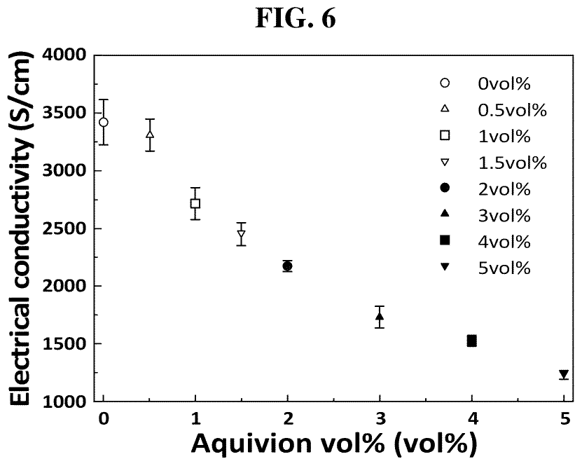

Furthermore, for the polymer composite electrodes prepared by adding the Aquivion polymer compound of Formula 3 to the conductive polymer PEDOT: PSS, followed by sulfuric acid treatment, according to Preparation Examples 6 to 12, the electrical conductivity of the polymer composite electrodes was measured depending on the concentration of the Aquivion polymer compound, with the results presented in FIG. 6.

FIGS. 5 and 6 show the electrical conductivities of the polymer composite electrodes prepared by adding the perfluorinated polymer compounds at various concentrations to the conductive polymer, followed by sulfuric acid treatment.

In addition, the thickness, sheet resistance, and electrical conductivity of the polymer composite electrodes, prepared by adding the perfluorinated polymer compounds at various concentrations to the conductive polymer, followed by sulfuric acid treatment, were measured, and the results are shown in Table 2 below:

TABLE 2

| | | Concentration of | | | Maximum | Average |
|---|---|---|---|---|---|---|
| | Perfluorinated | Perfluorinated | | Sheet | Electrical | Electrical |
| | Polymer | Polymer | Thickness | Resistance | Conductivity | Conductivity |
| Examples | Compound | Compound (vol %) | (nm) | (Ohm/cm²) | (S/cm) | (S/cm) |
| Preparation | Nafion^{a)} | 10 | 66 | 70.2112 | 2712 | 2173 ± 247 |
| Example 1 | | | | | | |
| Preparation | Nafion | 1 | 45 | 65.823 | 3533 | 3310 ± 160 |
| Example 2 | | | | | | |
| Preparation | Nafion | 5 | 53 | 68.0171 | 2949 | 2601 ± 180 |
| Example 3 | | | | | | |
| Preparation | Nafion | 15 | 79 | 72.4053 | 1841 | 1732 ± 107 |
| Example 4 | | | | | | |
| Preparation | Nafion | 20 | 91 | 77.89055 | 1523 | 1455 ± 57 |
| Example 5 | | | | | | |
| Preparation | Aquivion^{b)} | 0.5 | 48 | 61.4348 | 3463 | 3312 + 138 |
| Example 6 | | | | | | |
| Preparation | Aquivion | 1 | 61 | 61.4348 | 2855 | 2718 ± 141 |
| Example 7 | | | | | | |
| Preparation | Aquivion | 1.5 | 64 | 61.4348 | 2583 | 2459 ± 99 |
| Example 8 | | | | | | |
| Preparation | Aquivion | 2 | 75 | 61.4348 | 2199 | 2171 ± 29 |
| Example 9 | | | | | | |
| Preparation | Aquivion | 3 | 91 | 63.6289 | 1788 | 1729 ± 84 |
| Example 10 | | | | | | |
| Preparation | Aquivion | 4 | 102 | 64.72595 | 1556 | 1522 ± 31 |
| Example 11 | | | | | | |
| Preparation | Aquivion | 5 | 128 | 65.823 | 1309 | 1235 ± 46 |
| Example 12 | | | | | | |
| Comparative | — | — | 42 | 65.823 | 3798 | 3421 ± 199 |
| Example 1 | | | | | | |

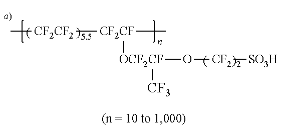

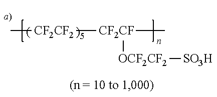

As shown in Table 2 and FIG. 5, the conductive polymer to which no perfluorinated polymer compound was added in Comparative Example 1, i.e., the PEDOT: PSS thin film, exhibited a sheet resistance of 65.823 Ohm/cm² and an average electrical conductivity of 3421±199 S/cm after sulfuric acid treatment. However, when the perfluorinated polymer compound (Nafion) of Formula 2 was added to the PEDOT: PSS according to the present inventive concept, it was found that as the concentration of the perfluorinated polymer compound increased from 1 to 20 vol %, after sulfuric acid treatment, the sheet resistance increased from 65.823 Ohm/cm² to 77.89055 Ohm/cm², and the average electrical conductivity decreased from 3310±160 S/cm to 1455±57 S/cm.

Similarly, as shown in Table 2 and FIG. 6, when the perfluorinated polymer compound (Aquivion) of Formula 3 was added to the PEDOT: PSS according to the present inventive concept, it was observed that as the concentration of the perfluorinated polymer compound increased from 0.5 to 5 vol %, after sulfuric acid treatment, the sheet resistance slightly increased from 61.4348 Ohm/cm² to 65.823 Ohm/cm², and the average electrical conductivity decreased from 3312±138 S/cm to 1235±46 S/cm.

Accordingly, although the polymer composite electrode according to the present inventive concept exhibits decreased electrical conductivity with increasing concentrations of the perfluorinated polymer compound of Formula 1 in the conductive polymer, an appropriate concentration of the perfluorinated polymer compound combined with sulfuric acid treatment allows for a high average electrical conductivity of 2,000 S/cm or higher, making it a promising alternative to ITO as an electrode in organic solar cells.

To achieve an average electrical conductivity of 2,000 S/cm or higher, it is preferable to adjust the concentration of the perfluorinated polymer compound to 10 vol % or lower when using the Nation polymer compound of Formula 2, and to adjust the concentration of the perfluorinated polymer compound to 2 vol % or lower when using the Aquivion polymer compound of Formula 3.

### Experimental Example 3: Change in Transmittance of the Polymer Composite Electrodes Depending on the Concentration of the Perfluorinated Polymer Compound

The following experiment was conducted to investigate the change in the transmittance of the electrodes depending on the concentration of the perfluorinated polymer compound added to the conductive polymer in the polymer composite electrodes of the present inventive concept.

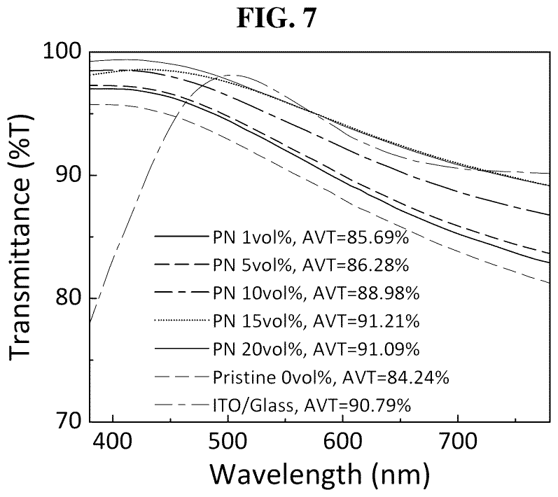

Specifically, the conductive polymer electrode of Comparative Example 1 was prepared using the conductive polymer PEDOT: PSS, followed by sulfuric acid treatment. In contrast, the polymer composite electrodes of Preparation Examples 1 to 5 were fabricated by incorporating the Nation polymer compound of Formula 2 into the conductive polymer, followed by sulfuric acid treatment. The transmittance of the polymer composite electrodes in the visible light region was subsequently measured as a function of the Nafion polymer compound concentration, with the results presented in FIG. 7.

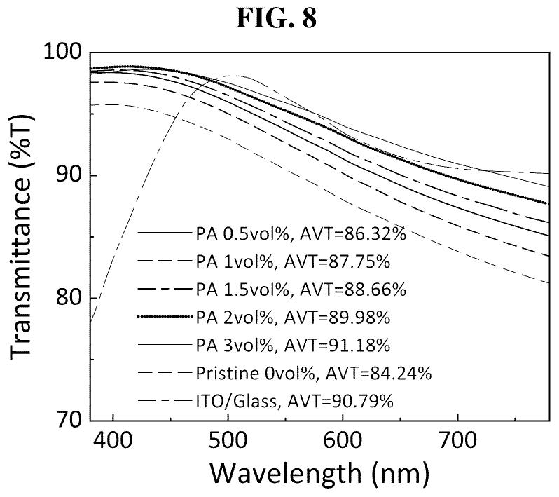

Moreover, for the polymer composite electrodes prepared by adding the Aquivion polymer compound of Formula 3 added to the conductive polymer PEDOT: PSS, followed by sulfuric acid treatment, according to Preparation Examples 6 to 12, the transmittance in the visible light region of the polymer composite electrodes was measured depending on the concentration of the Aquivion polymer compound, with the results presented in FIG. 8.

FIGS. 7 and 8 show the transmittance in the visible light region of polymer composite electrodes prepared by adding the perfluorinated polymer compounds at various concentrations to the conductive polymer, followed by sulfuric acid treatment.

Furthermore, the transmittance in the visible light region (400 to 700 nm) of the polymer composite electrodes, prepared by adding the perfluorinated polymer compounds at various concentrations to the conductive polymer, followed by sulfuric acid treatment, was measured, and the results are shown in Table 3 below:

TABLE 3

| | | Concentration of | |
|---|---|---|---|
| | Perfluorinated | Perfluorinated Polymer | |
| Examples | Polymer Compound | Compound (vol %) | Transmittance (%) |
| Preparation | Nafion^{a)} | 10 | 88.98 |
| Example 1 | | | |
| Preparation | Nafion | 1 | 85.69 |
| Example 2 | | | |
| Preparation | Nafion | 5 | 86.28 |
| Example 3 | | | |
| Preparation | Nafion | 15 | 91.21 |
| Example 4 | | | |
| Preparation | Nafion | 20 | 91.09 |
| Example 5 | | | |
| Preparation | Aquivion^{b)} | 0.5 | 86.32 |
| Example 6 | | | |
| Preparation | Aquivion | 1 | 87.75 |
| Example 7 | | | |
| Preparation | Aquivion | 1.5 | 88.66 |
| Example 8 | | | |
| Preparation | Aquivion | 2 | 89.98 |
| Example 9 | | | |
| Preparation | Aquivion | 3 | 91.18 |
| Example 10 | | | |
| Comparative | — | — | 84.24 |
| Example 1 | | | |
| Comparative | | | 90.79 |
| Example^{c)} | | | |

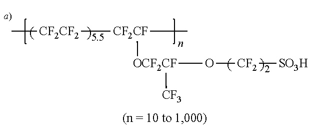

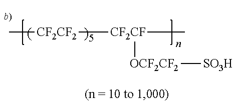

^{c)}ITO/Glass

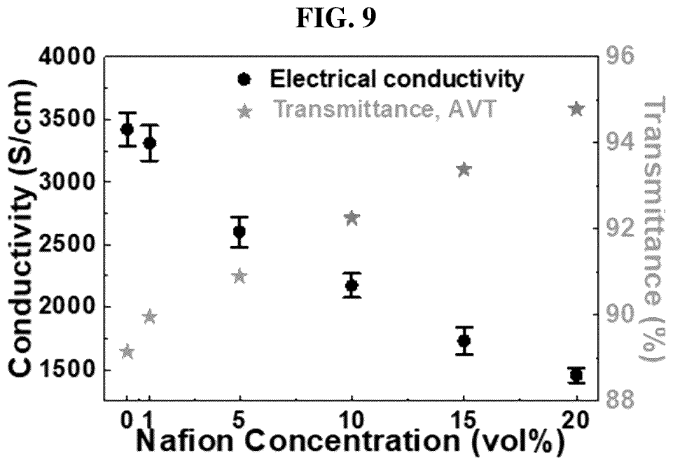

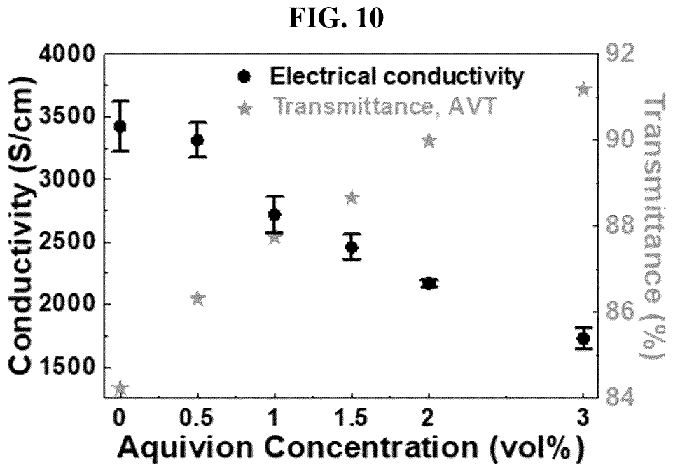

In addition, the conductive polymer electrode of Comparative Example 1 was prepared using the conductive polymer PEDOT: PSS, followed by sulfuric acid treatment. In contrast, the polymer composite electrodes of Preparation Examples 1 to 5 were fabricated by incorporating the Nafion polymer compound of Formula 2 into the conductive polymer, followed by sulfuric acid treatment. The changes in electrical conductivity and visible light transmittance were measured depending on the concentration of the perfluorinated polymer compound, with the results presented in FIG. 9. Additionally, for the polymer composite electrodes prepared by adding the perfluorinated polymer compound of formula 3 to the conductive polymer PEDOT: PSS, followed by sulfuric acid treatment, according to Preparation Examples 6 to 12, the changes in electrical conductivity and visible light transmittance were measured depending on the concentration of the perfluorinated polymer compound, with the results presented in FIG. 10.

As shown in Table 3, and in FIGS. 7 and 8, the transmittance was found to increase proportionally with the increased concentration of the perfluorinated polymer compound. Furthermore, as shown in FIGS. 9 and 10, the electrical conductivity was found to decrease with the increased concentration of the perfluorinated polymer compound.

Accordingly, to fabricate an electrode with a high transmittance of at least 85% in the visible light region, an average electrical conductivity of 2,000 S/cm or higher, and a work function energy level of approximately −5.5 eV—sufficient for matching the HOMO energy level of the photoactive layer—it is preferable that the concentration of the perfluorinated polymer compound of Formula 2 ranges from 1 vol % to 10 vol % relative to the PEDOT: PSS conductive polymer solution. Additionally, the concentration of the perfluorinated polymer compound of Formula 3 is preferably within the range of 0.5 vol % to 2 vol % relative to the PEDOT: PSS conductive polymer solution.

### Preparation Example 13: Fabrication of Organic Solar Cell

An organic solar cell with the structure shown in FIG. 11 was fabricated through the following method.

First, a PEDOT: PSS-based polymer composite electrode 10 was prepared as the anode on a glass substrate 5 using the method described in Preparation Example 1. Next, a bulk heterojunction (BHJ) layer was deposited as the photoactive layer 20 with a thickness of 100 nm by co-evaporating the electron donor material PM6 of Formula 4 below, and the electron acceptor material Y6 of Formula 5 below. Subsequently, a ZnO nanoparticle layer 30 with a thickness of 30 nm was deposited as the electron transport layer, and finally, an Al electrode 40 was deposited, thereby completing the fabrication of the organic solar cell.

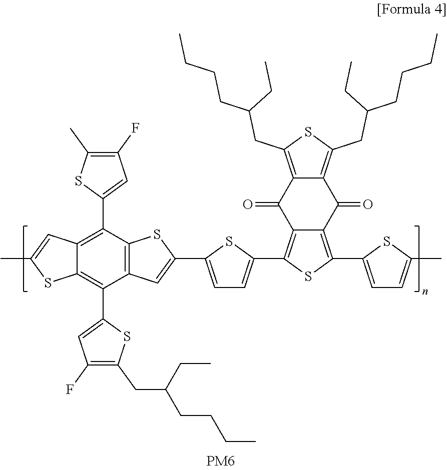

where n=100 to 2,000.

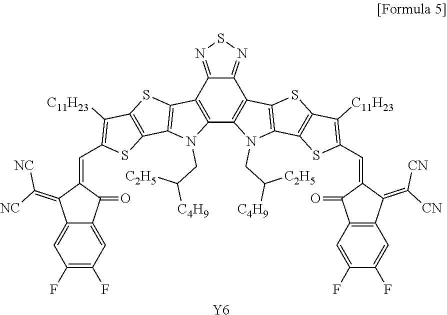

### Preparation Example 14: Fabrication of Organic Solar Cell

An organic solar cell was fabricated in the same manner as in Preparation Example 13, except that a bulk heterojunction layer (P3HT: PC₆₁BM), formed by co-evaporating the P3HT polymer of Formula 6 below and PC₆₁BM of Formula 7 below, was used as the photoactive layer instead of PM6: Y6.

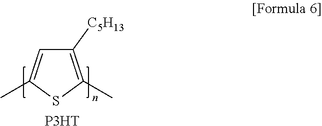

where n=1,000 to 50,000.

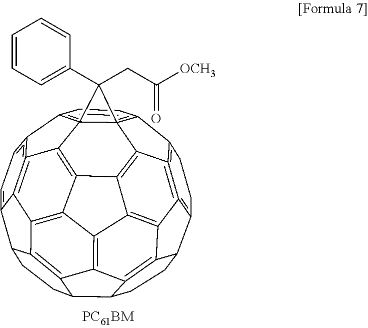

### Preparation Example 15: Fabrication of Organic Solar Cell

An organic solar cell was fabricated in the same manner as in Preparation Example 13, except that a bulk heterojunction layer (PTB7-Th: IEICO-4F), formed by co-evaporating the PTB7-Th polymer of Formula 8 below and IEICO-4F of Formula 9 below, was used as the photoactive layer instead of PM6: Y6.

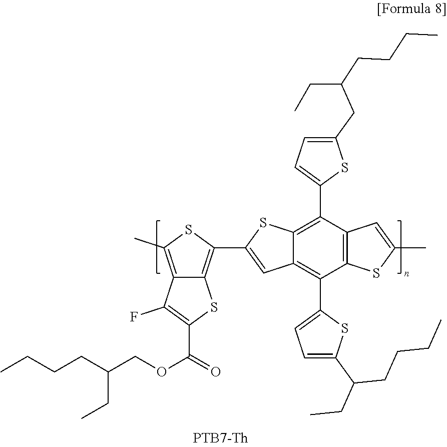

where n=50 to 3,000.

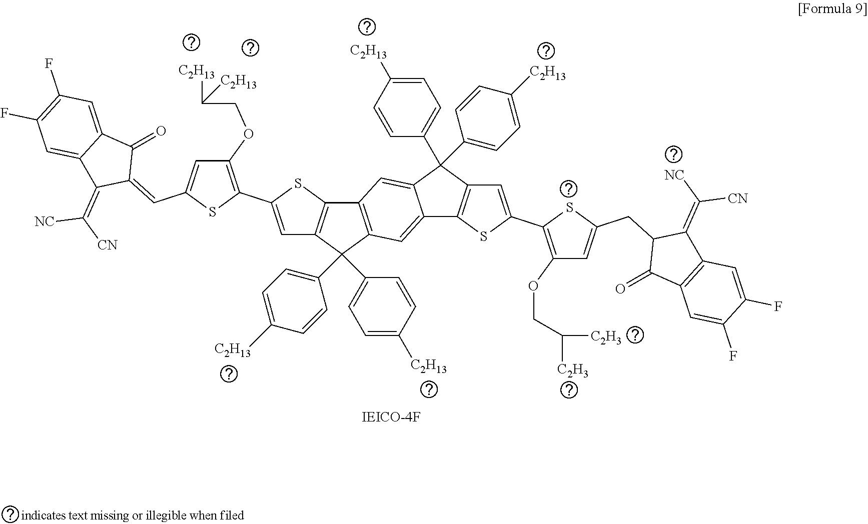

### Preparation Example 16: Fabrication of Organic Solar Cell

An organic solar cell was fabricated in the same manner as in Preparation Example 13, except that a bulk heterojunction layer (PTB7-Th: Eh-IDTBR), formed by co-evaporating the PTB7-Th polymer of Formula 8 and Eh-IDTBR of Formula 10 below, was used as the photoactive layer instead of PM6: Y6.

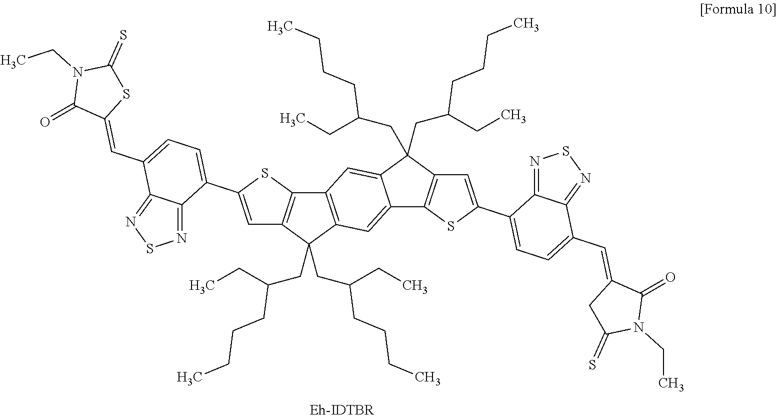 [SMILES: CCCCC(CC)CC1(CC(CC)CCCC)c2cc3c(cc2-c2sc(-c4ccc(/C=C5\SC(=S)N(CC)C5=O)c5nsnc45)cc21)C(CC(CC)CCCC)(CC(CC)CCCC)c1cc(-c2ccc(/C=C4\CC(=S)N(CC)C4=O)c4nsnc24)sc1-3]

### Preparation Example 17: Fabrication of Organic Solar Cell

An organic solar cell was fabricated in the same manner as in Preparation Example 13, except that a bulk heterojunction layer (PBDB-T: ITIC-M), formed by co-evaporating the PBDB-T polymer of Formula 11 below and ITIC-M of Formula 12 below, was used as the photoactive layer instead of PM6: Y6.

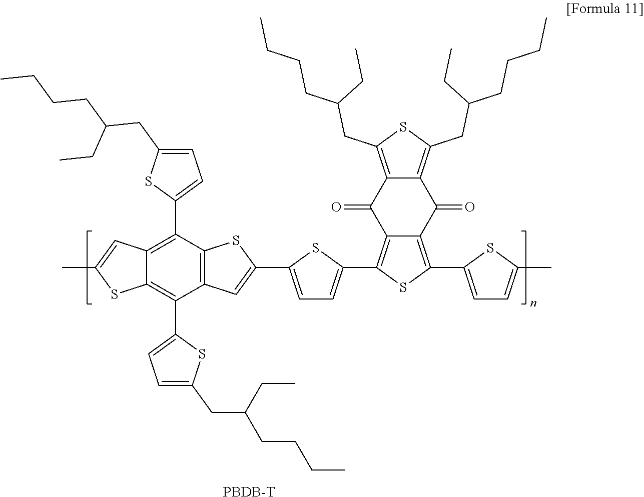

where n=100 to 2,000.

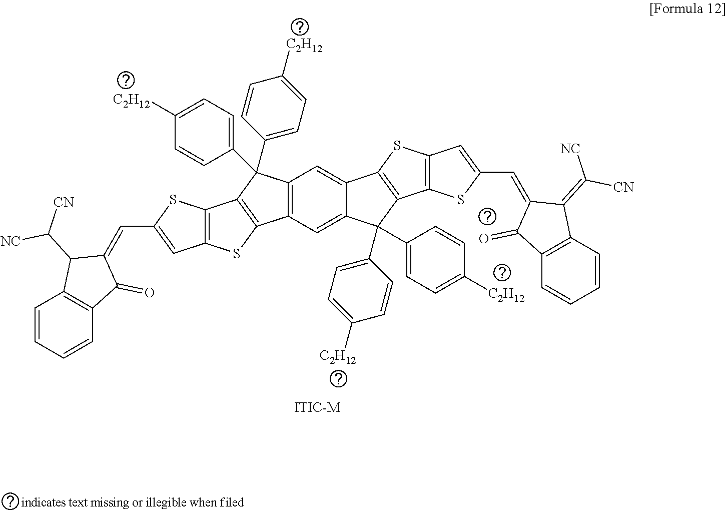

### Comparative Example 3: Fabrication of Organic Solar Cell

An organic solar cell was fabricated in the same manner as in Preparation Example 13, except that a PEDOT: PSS electrode prepared in Comparative Example 1 was used as the anode instead of the electrode prepared in Preparation Example 1.

### Comparative Example 4: Fabrication of Organic Solar Cell

An organic solar cell was fabricated in the same manner as in Preparation Example 13, except that an ITO electrode was used as the anode.

### Comparative Example 5: Fabrication of Organic Solar Cell

An organic solar cell was fabricated in the same manner as in Preparation Example 13, except that an ITO electrode was used as the anode on a glass substrate, and PEDOT: PSS (1:6 w/w, Al4083) was deposited as a hole transport layer between the anode and the photoactive layer.

### Comparative Example 6: Fabrication of Organic Solar Cell

An organic solar cell was fabricated in the same manner as in Preparation Example 14, except that an ITO electrode was used as the anode.

### Comparative Example 7: Fabrication of Organic Solar Cell

An organic solar cell was fabricated in the same manner as in Preparation Example 15, except that an ITO electrode was used as the anode.

### Comparative Example 8: Fabrication of Organic Solar Cell

An organic solar cell was fabricated in the same manner as in Preparation Example 16, except that an ITO electrode was used as the anode.

### Comparative Example 9: Fabrication of Organic Solar Cell

An organic solar cell was fabricated in the same manner as in Preparation Example 17, except that an ITO electrode was used as the anode.

### Experimental Example 4: Performance Evaluation of Organic Solar Cells

To evaluate the performance of organic solar cells comprising the polymer composite electrode according to the present inventive concept in comparison with conventional organic solar cells comprising an ITO electrode, performance parameters such as open-circuit voltage (V_{OC}), short-circuit current density (J_{SC}), fill factor (FF), and power conversion efficiency (PCE) were measured for the organic solar cells prepared in Preparation Example 13 and Comparative Examples 3 to 5, and the results are shown in Table 4 below:

TABLE 4

| | | Presence of | Open- | Short-Circuit | | Power |
|---|---|---|---|---|---|---|
| | | Hole | Circuit | Current | Fill | Conversion |
| | | Transport | Voltage | Density | Factor | Efficiency |
| Examples | Anode | Layer | (V_{OC}, V) | (J_{SC}, mA/cm²) | (FF, %) | (PCE, %) |
| Preparation | Polymer | No | 0.823 | 25.9 | 66.2 | 14.2 |
| Example 13 | Composite | | | | | |
| | Electrode | | | | | |
| Comparative | PEDOT:PSS | No | 0.790 | 24.8 | 65.0 | 12.7 |
| Example 3 | | | | | | |
| Comparative | ITO | No | 0.548 | 24.4 | 57.7 | 7.7 |
| Example 4 | | | | | | |
| Comparative | ITO | Yes | 0.834 | 25.0 | 69.7 | 14.5 |
| Example 5 | | | | | | |

As shown in Table 4, the polymer composite electrode of the present inventive concept achieves a power conversion efficiency (PCE) comparable to that of conventional organic solar cells incorporating an ITO electrode and a hole transport layer, even without the inclusion of the hole transport layer. When compared to organic solar cells containing only an ITO electrode, without a hole transport layer, under the same conditions, the polymer composite electrode demonstrates approximately twice the power conversion efficiency, confirming the superior performance of the organic solar cell.

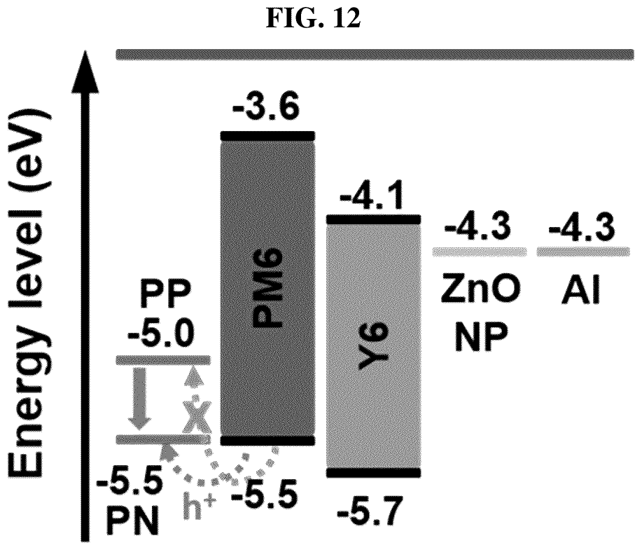

FIG. 12 is an energy band diagram of the organic solar cells fabricated in Preparation Example 13 and Comparative Example 4.

Referring to FIG. 12, in the organic solar cells, the conventional ITO electrode has a work function of approximately −5.0 eV, which results in a significant energy gap with the HOMO energy level of the photoactive layer (PM6) (−5.5 eV), making hole transport difficult between the ITO electrode and the photoactive layer. However, the polymer composite electrode (PN) according to the present inventive concept is designed to adjust its work function to match the HOMO energy level of the photoactive layer (PM6). This enables efficient hole transport between the electrode and the organic photoactive layer, even without the inclusion of the hole transport layer, resulting in excellent organic solar cell performance.

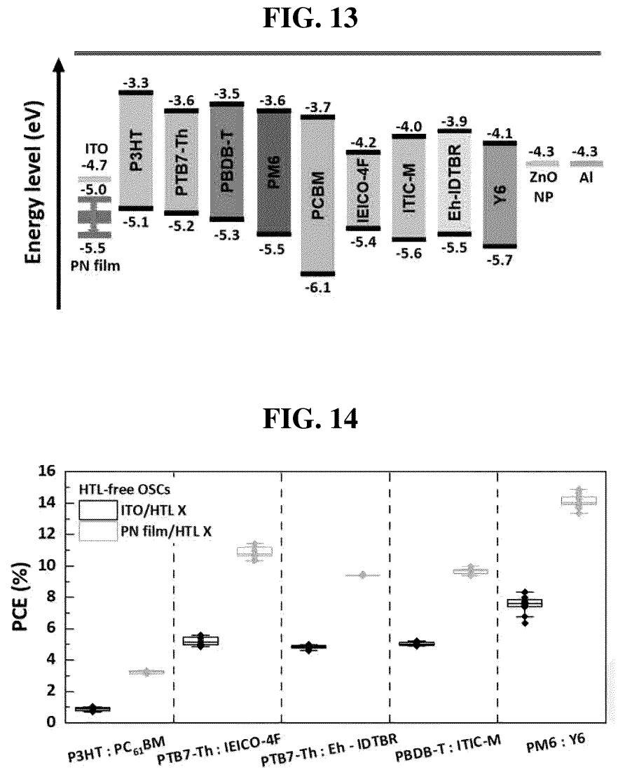

FIG. 13 is an energy band diagram of organic electronic devices fabricated according to embodiments of the present inventive concept, comprising various types of photoactive layer materials.

Referring to FIG. 13, the polymer composite electrode (PN film) according to the present inventive concept can adjust its work function from −5.0 eV to −5.5 eV by varying the concentration of the added perfluorinated polymer compound. Therefore, even without a hole transport layer, it can be effectively applied in organic electronic devices, such as organic solar cells, with various photoactive layer materials, whose HOMO is in the range of −5.0 eV to −5.5 eV.

For organic solar cells incorporating various types of photoactive layer materials, the performance of organic solar cells comprising the polymer composite electrode without a hole transport layer according to the present inventive concept was measured and compared with that of organic solar cells comprising an ITO electrode without a hole transport layer.

Specifically, the power conversion efficiency (PCE) of the organic solar cells comprising the polymer composite electrode without a hole transport layer, fabricated in Preparation Examples 13 to 17, was measured and compared with that of the organic solar cells comprising an ITO electrode without a hole transport layer, fabricated in Comparative Examples 4 and Comparative Examples 6 to 9, and the results are shown in FIG. 14.

As shown in FIG. 14, it was confirmed that, regardless of the type of photoactive layer material used, the organic solar cells comprising the polymer composite electrode of the present inventive concept without a hole transport layer exhibited significantly higher power conversion efficiency compared to those comprising an ITO electrode under the same conditions.

Accordingly, the polymer composite electrode according to the present inventive concept, prepared by adding a perfluorinated polymer compound of Formula 1 to a conductive polymer, followed by sulfuric acid treatment, exhibits a high transmittance of 85% or more in the visible light region and an average electrical conductivity of 2,000 S/cm or higher. Moreover, the work function of the polymer composite electrode can be matched to the highest occupied molecular orbital (HOMO) energy level of the photoactive layer by adjusting the concentration of the perfluorinated polymer compound of Formula 1, thereby enhancing the performance, such as power conversion efficiency, in optoelectronic devices even in the absence of a hole transport layer.

Furthermore, the polymer composite electrode may be fabricated using a solution-based process, which enables efficient electrode formation for optoelectronic devices.

It should be understood that the embodiments of the present inventive concept described in this specification and illustrated in the accompanying drawings are provided as specific examples to aid comprehension and are not intended to limit the scope of the inventive concept. Various modifications and alterations to these embodiments may be made by those skilled in the art without departing from the spirit and scope of the inventive concept.

### Brief Description of Reference Numerals

5: substrate
10: polymer composite electrode as an anode according to an embodiment of the
present inventive concept
20: photoactive layer
30: electron transport layer
40: cathode
50: power supply

What is claimed is:

1. A method for manufacturing a polymer composite electrode, the method comprising:
a step (S10) of preparing a polymer composite solution by mixing a perfluorinated polymer compound represented by Formula 1 below with a conductive polymer solution;
a step (S20) of forming a polymer composite thin film by applying the polymer composite solution onto a substrate;
a step (S30) of treating the polymer composite thin film with sulfuric acid; and
a step (S40) of washing and drying the polymer composite thin film treated with sulfuric acid to fabricate a polymer composite electrode: 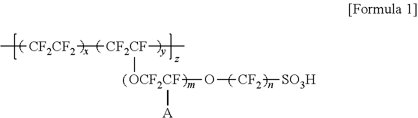
where x is a real number from 1 to 20,
y is a real number from 1 and 2,
z is a real number from 10 to 1,000,
A is F or CF₃,
m is a real number of 0 or 1, and
n is a real number from 1 to 20.

2. The method for manufacturing a polymer composite electrode according to claim 1, wherein the perfluorinated polymer compound of Formula 1 is a polymer represented by Formula 2 or Formula 3 below: 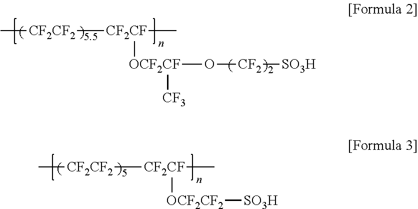
where n is a real number from 10 to 1,000.

3. The method for manufacturing a polymer composite electrode according to claim 2, wherein if the conductive polymer is a PEDOT: PSS polymer and the perfluorinated polymer compound is a polymer of Formula 2, the concentration of the perfluorinated polymer compound is in the range of 1 vol % to 10 vol % based on the PEDOT: PSS polymer solution.

4. The method for manufacturing a polymer composite electrode according to claim 2, wherein if the conductive polymer is a PEDOT: PSS polymer and the perfluorinated polymer compound is a polymer of Formula 3, the concentration of the perfluorinated polymer compound is in the range of 0.5 vol % to 2 vol % based on the PEDOT: PSS polymer solution.

5. The method for manufacturing a polymer composite electrode according to claim 1, wherein the step of treating the polymer composite thin film with sulfuric acid comprises immersing the polymer composite thin film in sulfuric acid.

6. The method for manufacturing a polymer composite electrode according to claim 1, wherein the step of washing the polymer composite thin film treated with sulfuric acid is carried out using water.

7. A polymer composite electrode prepared by mixing a PEDOT: PSS conductive polymer and a perfluorinated polymer compound of Formula 1 below,
wherein the polymer composite electrode has a work function, which is reduced to −5.4 eV or lower depending on the concentration of the perfluorinated polymer compound of Formula 1 mixed with the conductive polymer, an average electrical conductivity of 2,000 S/cm or higher, and a transmittance of 85% or more in the visible light region: 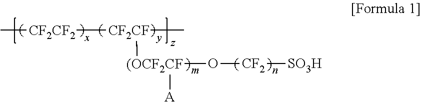
where x is a real number from 1 to 20,
y is a real number from 1 and 2,
z is a real number from 10 to 1,000,
A is F or CF₃,
m is a real number of 0 or 1, and
n is a real number from 1 to 20.

8. The polymer composite electrode according to claim 7, wherein the perfluorinated polymer compound of Formula 1 is a polymer represented by Formula 2 or Formula 3 below: 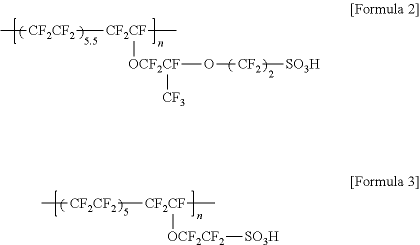
where n is a real number from 10 to 1,000.

9. An organic electronic device comprising:
a substrate;
an anode formed on the substrate;
a photoactive layer formed on the anode; and
a cathode located on the photoactive layer,
wherein the anode is a polymer composite electrode prepared by mixing a PEDOT: PSS conductive polymer and a perfluorinated polymer compound of Formula 1 below, and
wherein the polymer composite electrode has a work function, which is reduced to −5.4 eV or lower depending on the concentration of the perfluorinated polymer compound of Formula 1 mixed with the conductive polymer, an average electrical conductivity of 2,000 S/cm or higher, and a transmittance of 85% or more in the visible light region: 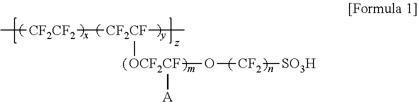
where x is a real number from 1 to 20,
y is a real number from 1 and 2,
z is a real number from 10 to 1,000,
A is F or CF₃,
m is a real number of 0 or 1, and
n is a real number from 1 to 20.

10. The organic electronic device according to claim 9, wherein the perfluorinated polymer compound of Formula 1 is a polymer represented by Formula 2 or Formula 3 below: 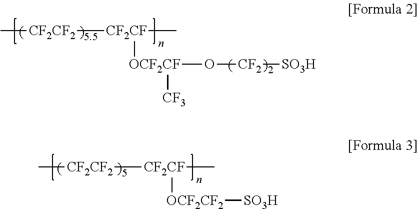
where n is a real number from 10 to 1,000.

11. The organic electronic device according to claim 9, wherein the work function of the polymer composite electrode is matched to the highest occupied molecular orbital (HOMO) energy level of the photoactive layer by adjusting the concentration of the perfluorinated polymer compound of Formula 1 mixed with the conductive polymer.

12. The organic electronic device according to claim 9, wherein the polymer composite electrode has an average electrical conductivity of 2,000 S/cm or higher and a transmittance of 85% or more in the visible light region.

13. The organic electronic device according to claim 9, wherein the photoactive layer is a light-emitting layer or a photoelectric conversion layer.

14. The organic electronic device according to claim 9, further comprising an electron transport layer between the photoactive layer and the cathode.
